(19) United States
(12) Patent Application Publication
(10) Pub. No.: US 2018/0261982 A1
(43) Pub. Date: Sep. 13, 2018

(54) SEMICONDUCTOR LASER

(71) Applicant: SUMITOMO ELECTRIC INDUSTRIES, LTD., Osaka (JP)

(72) Inventor: Tsukuru KATSUYAMA, Yokohama-shi (JP)

(73) Assignee: SUMITOMO ELECTRIC INDUSTRIES, LTD., Osaka (JP)

(21) Appl. No.: 15/881,977

(22) Filed: Jan. 29, 2018

(30) Foreign Application Priority Data
Mar. 10, 2017 (JP) 2017-046518

(51) Int. Cl. H01S 5/34; H01S 5/227; H01S 5/042; H01S 5/12; H01S 5/02; H01S 5/343

(52) U.S. Cl. CPC H01S 5/3402; H01S 5/227; H01S 5/0425; H01S 5/3408; H01S 5/028; H01S 5/0206; H01S 5/34366; H01S 5/3434; H01S 5/34346; H01S 5/12

(57) ABSTRACT

A semiconductor laser includes a substrate having a principal surface; an active region having a top surface and a side surface, the active region including a plurality of quantum well structures arranged in a direction of a first axis intersecting the principal surface of the substrate; a semiconductor mesa having first and second portions arranged in a direction of a waveguide axis above the principal surface of the substrate, the semiconductor mesa including the active region; a first semiconductor region of a first conductivity type on the top and side surfaces of the active region in the first portion of the semiconductor mesa; and a collector region on the side surface of the active region in the second portion of the semiconductor mesa.

### BACKGROUND OF THE INVENTION

### 1. Field of the Invention

The present invention relates to a semiconductor laser. More particularly, the present invention relates to a semiconductor laser that has a radiation mechanism using unipolar carriers.

### 2. Description of the Related Art

Japanese Unexamined Patent Application Publication No. 8-279647 discloses a quantum cascade laser.

### SUMMARY OF THE INVENTION

A quantum cascade laser (QCL) emits light by using intersubband transitions of unipolar carries in active layers arranged in series, which is sometimes called as the cascaded radiative transition. In order to enhance an efficiency of the cascaded radiative transition, energy levels in one active layer are necessary to be aligned with energy levels in active layers next to the one active layer. Specifically, a higher energy level in the one active layer is aligned with a lower energy level in the upstream active layer, and a lower energy level in the one active layer is aligned with a higher energy level in the downstream active layer. Such a cascaded radiative transition may enhance the optical gain in infrared wavelengths, and resultantly, the cascaded radiative transition realizes the laser oscillation in infrared regions. However, the cascaded radiative transition is inevitable to be supplied with a large bias, which resultantly prohibits a cascade structure of the active layers from operating in reduced biases.

A semiconductor laser according to one aspect of the present invention includes a substrate having a principal surface; an active region having a top surface and a side surface, the active region including a plurality of quantum well structures arranged in a direction of a first axis intersecting the principal surface of the substrate; a semiconductor mesa having first and second portions arranged in a direction of a waveguide axis above the principal surface of the substrate, the semiconductor mesa including the active region; a first semiconductor region of a first conductivity type on the top and side surfaces of the active region in the first portion of the semiconductor mesa; and a collector region on the side surface of the active region in the second portion of the semiconductor mesa.

Objects, features, and advantages of the invention will become more apparent from the following detailed description of preferred embodiments of the invention with reference to the accompanying drawings.

### BRIEF DESCRIPTION OF THE DRAWINGS

FIGS. 1A to 1D schematically show a semiconductor laser according to one embodiment.

FIGS. 2A, 2B, and 2C schematically show the semiconductor laser according to this embodiment.

FIG. 3 shows the structure of an active region of the semiconductor laser according to this embodiment.

FIG. 4 shows the structure of an emitter region and the active region of the semiconductor laser according to this embodiment.

FIG. 5 shows the structure of a collector region and the active region of the semiconductor laser according to this embodiment.

FIG. 6 schematically shows the energy level and layer structure of quantum well structures in Example 1.

FIG. 7 schematically shows the energy level and layer structure of quantum well structures in Example 2.

FIGS. 8A, 8B, and 8C schematically show the supply of carriers from the emitter region into the active region of the semiconductor laser according to this embodiment.

FIGS. 9A, 9B, and 9C schematically show the supply of carriers from the emitter region into the active region of the semiconductor laser according to this embodiment.

FIGS. 10A and 10B schematically show the semiconductor laser according to this embodiment.

FIGS. 11A to 11D schematically show the main steps of a method for manufacturing the semiconductor laser according to this embodiment.

FIGS. 12A to 12D schematically show the main steps of the method for manufacturing the semiconductor laser according to this embodiment.

FIGS. 13A to 13D schematically show the main steps of the method for manufacturing the semiconductor laser according to this embodiment.

FIGS. 14A to 14D schematically show the main steps of another method for manufacturing the semiconductor laser according to this embodiment.

FIGS. 15A to 15D schematically show the main steps of the other method for manufacturing the semiconductor laser according to this embodiment.

### DESCRIPTION OF THE PREFERRED EMBODIMENTS

Continuing from the above description, some specific embodiments will now be described.

A semiconductor laser according to an embodiment includes (a) a substrate having a principal surface; (b) an active region having a top surface and a side surface, the active region including a plurality of quantum well structures arranged in a direction of a first axis intersecting the principal surface of the substrate; (c) a semiconductor mesa having first and second portions arranged in a direction of a waveguide axis above the principal surface of the substrate, the semiconductor mesa including the active region; (d) a first semiconductor region of a first conductivity type on the top and side surfaces of the active region in the first portion of the semiconductor mesa; and (e) a collector region on the side surface of the active region in the second portion of the semiconductor mesa.

In this semiconductor laser, the first semiconductor region is of the first conductivity type. The active region generates light by utilizing intersubband transitions of unipolar carriers, i.e., electrons or holes. The first semiconductor region supplies carriers to the active region through the top and side surfaces of the active region. The collector region receives carriers from the active region through the side surface of the active region. As carriers are injected from the top surface of the active region into the active region, the carriers injected from the first semiconductor region spread over the stack of quantum well structures arranged in the direction of the first axis. In addition, as carriers are injected from the side surface of the active region into the active region, the carriers injected from the first semiconductor region may be directly supplied to the quantum well structures without passing through the barriers between the quantum well structures. The carriers in the individual quantum well structures travel through the first and second portions of the semiconductor mesa. In addition, the carriers travel from the first portion to the second portion of the semiconductor mesa. Simultaneously, light is generated through optical transitions in the quantum well structures. The carriers that have undergone transitions flow through the side surface of the active region into the collector region.

In the semiconductor laser according to an embodiment, preferably, each of the quantum well structures includes a first well layer, a second well layer, a first barrier layer, and a second barrier layer. The first barrier layer separates the first well layer from the second well layer. The first well layer separates the first barrier layer from the second barrier layer.

In this semiconductor laser, the quantum well structures readily provide an upper energy level and a lower energy level having an energy level lower than that of the upper energy level for unipolar carriers. In addition, the quantum well structures may also provide a relaxation energy level having an energy level lower than that of the lower energy level. The relaxation of unipolar carriers from the lower energy level to the relaxation energy level occurs in a time shorter than the time for transition from the upper energy level to the lower energy level. The carriers that have transitioned from the upper energy level to the lower energy level relax at high speed to the relaxation energy level.

In the semiconductor laser according to an embodiment, preferably, the active region includes a plurality of unit cells arranged in the direction of the first axis. Each of the unit cells includes the first well layer, the second well layer, the first barrier layer, and the second barrier layer. In addition, the first barrier layer has a thickness smaller than that of the second barrier layer.

In this semiconductor laser, the first barrier layer has a thickness smaller than that of the second barrier layer. Thus, the first well layer and the second well layer in each unit cell are coupled with each other more closely than with another well layer separated by the second barrier layer in the unit cell.

In the semiconductor laser according to an embodiment, preferably, each of the quantum well structures includes a barrier layer extending in a plane intersecting the direction of the first axis. The barrier layer is partially or completely doped with a dopant of the first conductivity type.

In this semiconductor laser, the doped barrier layer is useful for injection into the well layers.

In the semiconductor laser according to an embodiment, preferably, the collector region includes a metal electrode extending in the direction of the first axis on the side surface of the active region.

In the semiconductor laser according to an embodiment, preferably, the collector region includes a second semiconductor region of the first conductivity type on the side surface of the active region.

In the semiconductor laser according to an embodiment, preferably, the semiconductor laser includes a plurality of basic structures, each of which includes the first semiconductor region, the first portion of the semiconductor mesa, the second semiconductor region, and the second portion of the semiconductor mesa. The basic structures are periodically arranged in the direction of the waveguide axis. In addition, the first semiconductor regions and the second semiconductor regions are alternately arranged in the direction of the waveguide axis.

This semiconductor laser has a gain-coupled distributed feedback structure.

The semiconductor laser according to an embodiment may further include a first electrode and a second electrode. The first electrode may be electrically connected to the first semiconductor region of the first conductivity type. The second electrode may be electrically connected to the collector region.

The findings of the present invention can be readily understood from the following detailed description with reference to the accompanying drawings, which are given by way of example. A semiconductor laser according to one embodiment of the present invention will now be described with reference to the accompanying drawings, where, if possible, like reference numerals denote like elements.

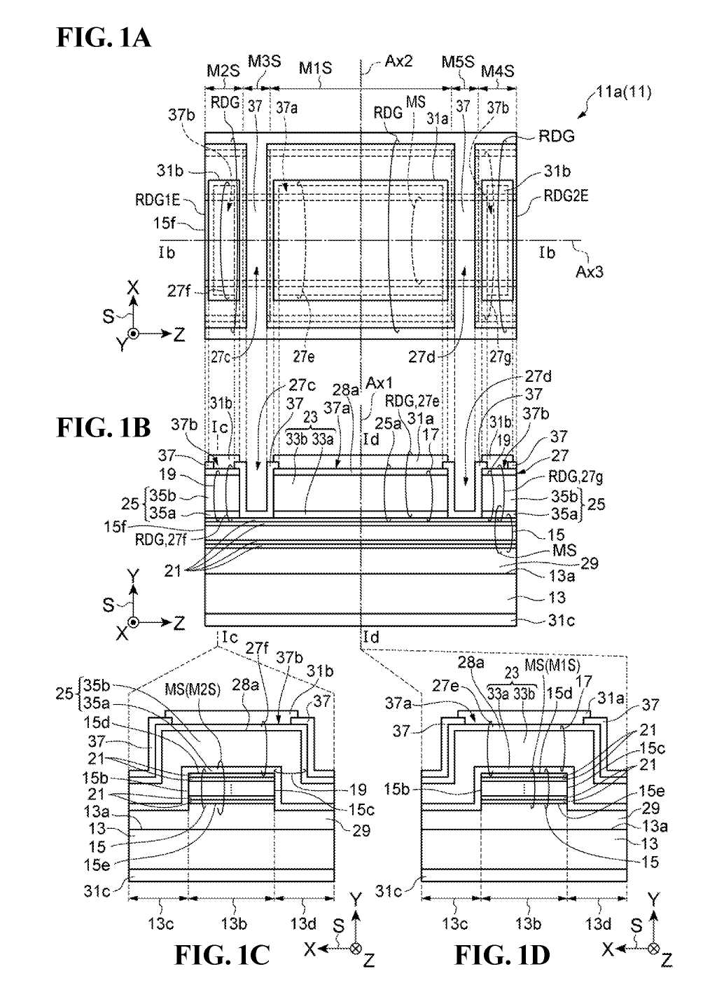

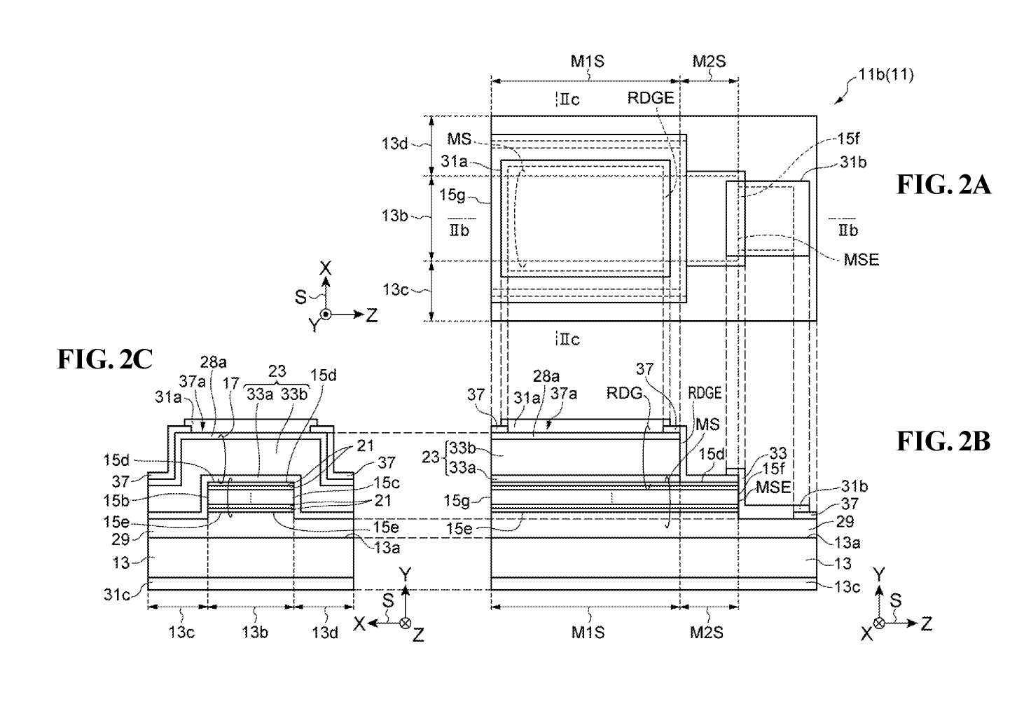

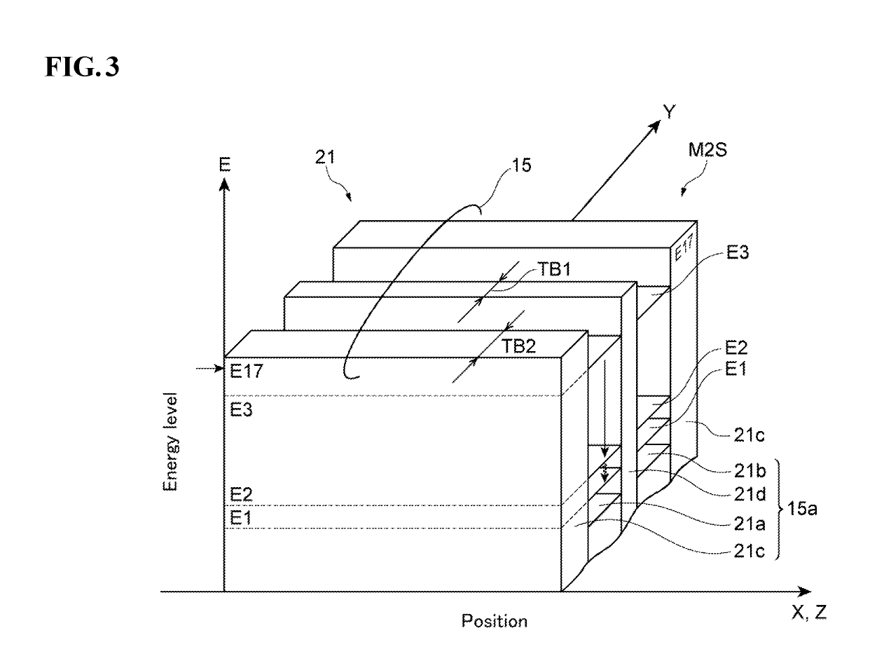

FIGS. 1A, 1B, 1C, and 1D schematically show a semiconductor laser according to this embodiment. FIG. 1A is a plan view of the semiconductor laser. FIG. 1B is sectional views taken along line Ib-Ib in FIG. 1A. FIG. 1C is sectional views taken along line Ic-Ic in FIG. 1B. FIG. 1D is sectional views taken along line Id-Id in FIG. 1B. FIGS. 2A, 2B, and 2C schematically show a semiconductor laser according to this embodiment. FIG. 2A is a plan view of the semiconductor laser. FIG. 2B is sectional views taken along line IIb-IIb in FIG. 2A. FIG. 2C is sectional views taken along line IIc-IIc in FIG. 2A. FIG. 3 schematically shows the quantum well structures and energy level of the semiconductor laser according to this embodiment. The vertical coordinate axis (vertical axis) indicates the energy level. The remaining two coordinate axes (horizontal axes) indicate the X- and Z-axes and the Y-axis for space coordinates. Although the description with reference to FIG. 3 is directed toward a configuration in which electrons serve as carriers, this description may also be read in the context of a configuration in which holes serve as carriers based on knowledge about semiconductor physics.

For ease of understanding, a Cartesian coordinate system S is shown in FIGS. 1A to 1D and FIGS. 2A to 2C. This semiconductor laser has, for example, a Fabry-Perot (FP) type laser structure or a distributed feedback (DFB) type laser structure. Referring to FIGS. 1A to 1D and FIGS. 2A to 2C, a semiconductor laser 11 (11a or 11b) according to this embodiment includes a substrate 13, an emitter region 17, collector regions 19, and a semiconductor mesa MS. The substrate 13 has a principal surface 13a. The semiconductor mesa MS includes an active region 15. The substrate 13, the active region 15, and the emitter region 17 are arranged in the direction of a first axis Ax1 intersecting the principal surface 13a (in this example, the Y-axis of the Cartesian coordinate system S). The active region is disposed on the principal surface 13a of the substrate 13. The active region 15 has a first side surface 15b, a second side surface 15c, a top surface 15d, a bottom surface 15e facing the top surface 15d, and a third side surface 15f. The third side surface 15f extends in the direction of a second axis Ax2 intersecting the first axis Ax1 (in this example, the X-axis of the Cartesian coordinate system S). The first side surface 15b, the second side surface 15c, the top surface 15d, and the bottom surface 15e extend in the direction of a third axis Ax3 intersecting the first axis Ax1 and the second axis Ax2 (in this example, the Z-axis of the Cartesian coordinate system S).

The principal surface 13a of the substrate 13 includes a first area 13b, a second area 13c, and a third area 13d. The first area 13b, the second area 13c, and the third area 13d extend in the direction of the third axis Ax3. The first area 13b is disposed between the second area 13c and the third area 13d. The emitter region 17 includes a first semiconductor region 23 that is disposed on the first side surface 15b and second side surface 15c of the active region 15. The semiconductor region 23 extends in the direction of a waveguide axis above the second area 13c and the third area 13d.

The active region 15 includes a plurality of quantum well structures 21. Each of the quantum well structures 21 is disposed on the principal surface 13a of the substrate 13. As shown in FIG. 3, the quantum well structures 21 in the active region 15 include unit cells 15a. The active region 15 includes a plurality of unit cells 15a arranged in the direction of the first axis Ax1. Specifically, each of the quantum well structure 21 includes a plurality of semiconductor layers (21a, 21b, 21c, and 21d) including well layers and barrier layers. These semiconductor layers (21a to 21d) are arranged in the direction of the first axis Ax1 intersecting the principal surface 13a.

The semiconductor mesa MS extends in the direction of the third axis Ax3 above the principal surface 13a of the substrate 13. The active region 15 in the semiconductor mesa MS extends in the direction of the third axis Ax3 above the principal surface 13a of the substrate 13. The semiconductor mesa MS has a first portion M1S and a second portion M2S. The first portion M1S and the second portion M2S are arranged in the direction of the waveguide axis (third axis Ax3) above the principal surface 13a of the substrate 13. The active region 15 is included in both the first portion M1S and the second portion M2S.

The first semiconductor region 23 in the emitter region 17 is disposed on the active region 15 in the first portion M1S of the semiconductor mesa MS. Specifically, the emitter region 17 is disposed on the top surface 15d of the active region 15. In addition, the emitter region 17 is disposed on the first side surface 15b and/or second side surface 15c of the active region 15.

The collector region 19 is separated from the emitter region 17 and is disposed on a side surface of the active region 15 in the semiconductor mesa MS. Specifically, the collector region 19 is disposed on at least one of the first side surface 15b, the second side surface 15c, and the third side surface 15f of the active region 15. The collector region 19 is also disposed on the top surface 15d of the active region 15. In this example, the collector region 19 is disposed on the first side surface 15b and second side surface 15c of the active region 15 above the second area 13c and the third area 13d, respectively. Alternatively, the collector region 19 is disposed on the third side surface 15f above the first area 13b. The collector region 19 includes a metal and/or a semiconductor.

In the semiconductor laser 11 (11a or 11b), the first semiconductor region 23 is of the first conductivity type. The active region 15 generates light by utilizing intersubband transitions of unipolar carriers, i.e., electrons or holes. That is, the active region 15 has a configuration different from those of conventional semiconductor lasers, which generate light by utilizing radiative transitions through the recombination of electrons and holes. The first semiconductor region 23 supplies carriers to the active region 15 through the first side surface 15b, second side surface 15c, and top surface 15d of the active region 15. The collector region 19 receives carriers from the active region 15 through the first side surface 15b, second side surface 15c, or third side surface 15f of the active region 15. As carriers are injected from the top surface 15d of the active region 15 into the active region 15, the carriers injected from the first semiconductor region 23 spread over the stack of quantum well structures 21 arranged in the direction of the first axis Ax1. The carriers in the individual quantum well structures 21 travel through the first portion M1S and second portion M2S of the semiconductor mesa MS, and through the quantum well structures 21 in the first and second portions (M1S and M2S) in the direction of the waveguide axis while generating light through optical transitions. The carriers that have undergone transitions flow through the first side surface 15b and second side surface 15c of the active region 15 into the collector region 19.

The first semiconductor region 23 of the emitter region 17 is disposed on the first portion M1S of the semiconductor mesa MS. Specifically, the emitter region 17 is disposed on the top surface 15d of the active region 15 in the first portion M1S. The emitter region 17 is also disposed on the first side surface 15b and/or second side surface 15c of the active region 15 in the first portion M1S. In this example, the emitter region 17 is disposed on the top surface 15d, the first side surface 15b, and the second side surface 15c of the active region 15 in the first portion M1S. The collector region 19 is disposed on a side surface of the active region 15 in the second portion M2S of the semiconductor mesa MS. Specifically, the collector region 19 is disposed on at least one of the first side surface 15b, the second side surface 15c, and the third side surface 15f of the active region 15 in the second portion M2S. The collector region 19 is also disposed on the top surface 15d of the active region 15 in the second portion M2S. In this example, the first portion M1S of the semiconductor mesa MS is longer than the second portion M2S of the semiconductor mesa MS. The first portion M1S, being longer, allows carriers to be injected from the emitter region 17 into the active region 15 over a larger cross-sectional area. By separating the first portion M1S from the second portion M2S, a travel path for optical transitions in the active region 15 may be provided for carriers.

The emitter region 17 is disposed on the top surface 15d and side surfaces (15b and 15c) of the active region 15 above the principal surface 13a of the substrate 13. In this example, the first semiconductor region 23 of the emitter region 17 extends from the second area 13c of the principal surface 13a along the first side surface 15b, the top surface 15d, and the second side surface 15c to the third area 13d of the principal surface 13a. Specifically, the first semiconductor region 23 is in contact with the top and side surfaces of the first portion M1S of the semiconductor mesa MS. The emitter region 17 includes one or a plurality of semiconductor layers.

A contact layer 28a is disposed on the emitter region 17. The emitter region 17 is in contact with the top surface 15d of the active region 15. The semiconductor laser 11 (11a or 11b) includes a first electrode 31a disposed on the emitter region 17 and a second electrode 31b connected to the collector region 19. The semiconductor laser 11 (11a or 11b) may, if necessary, include a metal film 31c disposed on the back surface 13e of the substrate 13. The first electrode 31a and the second electrode 31b are electrically connected to the emitter region 17 and the collector region 19, respectively. The first electrode 31a is in ohmic contact with the first-conductivity-type semiconductor layer in the emitter region 17.

The semiconductor laser 11 (11a or 11b) includes a cladding layer 29 disposed on the principal surface 13a of the substrate 13. The mesa structure MS is disposed on the cladding layer 29 in the first area 13b. The cladding layer 29 is located between the bottom surface 15e of the active region 15 and the substrate 13. The cladding layer 29 is formed of a semiconductor having a resistivity higher than the average resistivity of the active region 15. In this example, the cladding layer 29 is formed of an insulating or semi-insulating semiconductor. The emitter region 17 extends in the direction of the third axis Ax3 above the top surface 15d, first side surface 15b, and second side surface 15c of the active region 15, and above a principal surface of the cladding layer 29 so as to form a ridge structure RDG. The ridge structure RDG covers the semiconductor mesa MS.

The cladding layer 29 has a refractive index lower than the average refractive index of the active region 15. The emitter region 17 also has a refractive index (or average refractive index) lower than the average refractive index of the active region 15. The arrangement of the active region 15, the emitter region 17, and the cladding layer 29 forms a waveguide structure. The light generated in the active region 15 is optically confined in the transverse direction by the emitter region 17. The light generated in the active region 15 is also optically confined in the perpendicular direction by the emitter region 17 and the cladding layer 29. The first semiconductor region 23 of the emitter region 17 disposed on the active region separates the first electrode 31a from the top surface of the semiconductor mesa MS in which light propagates.

The carriers supplied from the emitter region 17 to the active region 15 are of the same conductivity type as those supplied from the active region 15 to the collector region 19. The semiconductor laser 11 (11a or 11b) utilizes unipolar carriers. The first portion M1S is separated from the second portion M2S in the direction of the waveguide axis. Thus, the emitter region 17 is electrically separated from the collector region 19. Carriers flow from the emitter region 17 through the active region 15 into the collector region 19 in the direction of the waveguide axis.

In this semiconductor laser 11, the active region 15 and the emitter region 17 are arranged in the direction of the first axis Ax1. The active region 15 disposed on the first area 13b and the collector regions 19 disposed on the second area 13c and the third area 13d are arranged in the direction of the second axis Ax2 intersecting the first axis Ax1. Unipolar carriers are supplied from the emitter region 17 over the quantum well structures 21 of the active region 15. These unipolar carriers generate light through optical transitions from upper to lower energy levels in the subbands of the quantum well structures 21 of the active region 15. The unipolar carriers at the lower energy level flow into the collector regions 19 through optical transitions in the active region 15. The unipolar carriers injected from the emitter region 17 are the same as those flowing into the collector regions 19. This semiconductor laser 11 utilizes optical transitions of unipolar carriers for light emission. Furthermore, the arrangement of the emitter region 17, the active region 15, and the collector regions 19 does not require cascaded radiative transitions of unipolar carriers for light emission. The semiconductor laser 11 may operate at a reduced voltage as compared to conventional quantum cascade semiconductor lasers that utilize optical transitions of unipolar carriers.

Several specific structures of the semiconductor laser 11 will now be described.

### First Structure

A semiconductor laser 11a (11) will now be described with reference to FIGS. 1A to 1D. In the semiconductor laser 11a, the semiconductor mesa MS extends from one end to the other end of the semiconductor laser 11a in the direction of the waveguide axis (third axis Ax3). Each collector region 19 includes a second semiconductor region 25 of the first conductivity type. The second semiconductor region 25 is disposed on at least one of the first side surface 15b and second side surface 15c of the active region 15. The portions of the second semiconductor region 25 of the collector region 19 that cover the first side surface 15b and second side surface 15c of the active region 15 extend in the direction of the waveguide axis above the second area 13c and the third area 13d, respectively. The second semiconductor region 25 is of the same conductivity type as the first semiconductor region 23. In this example, the second semiconductor region 25 is disposed above each of the second area 13c and the third area 13d and is in contact with the first side surface 15b and second side surface 15c of the active region 15. The second semiconductor region 25 is also disposed on the active region 15 above the first area 13b and is in contact with the top surface 15d of the active region 15. The second semiconductor region 25 includes one or a plurality of semiconductor layers.

The portion of the second semiconductor region 25 of each collector region 19 on the top surface 15d of the active region 15 may separate the second electrode 31b from the top surface 15d of the active region 15, which generate laser light.

A segmented structure 27 is disposed on the semiconductor mesa MS that is disposed on the cladding layer 29 above the first area 13b of the principal surface 13a of the substrate 13. In this example, the segmented structure 27 includes a first segmentation groove 27c, a first island 27e, and a second island 27f (and, if necessary, a second segmentation groove 27d and a third island 27g). In addition to the first portion M1S and the second portion M2S, the semiconductor mesa MS includes a third portion M3S. If necessary, the semiconductor mesa MS further includes a fourth portion M4S and a fifth portion M5S. In this example, the fourth portion M4S has the same structure as the second portion M2S. The fifth portion M5S has the same structure as the third portion M3S. The second portion M2S, the third portion M3S, and the first portion M1S are arranged in sequence in the direction of the third axis Ax3. Alternatively, the second portion M2S, the third portion M3S, the first portion M1S, the fifth portion M5S, and the fourth portion M4S are arranged in sequence in the direction of the third axis Ax3. The second island 27f, the first segmentation groove 27c, the first island 27e, the second segmentation groove 27d, and the third island 27g are disposed on the second portion M2S, the third portion M3S, the first portion M1S, the fifth portion M5S, and the fourth portion M4S, respectively. The first segmentation groove 27c and the second segmentation groove 27d extend from the surface of the contact layer 28a to the top surface 15d of the active region 15 in the direction of the first axis Ax1. The first island 27e includes the first semiconductor region 23 of the emitter region 17. Each of the second island 27f and the third island 27g includes the second semiconductor region 25 of the collector region 19. The first segmentation groove 27c separates the first island 27e including the first semiconductor region 23 of the emitter region 17 from the second island 27f including the second semiconductor region 25 of the collector region 19 to insulate the emitter region 17 from the collector region 19. The second segmentation groove 27d separates the first island 27e including the first semiconductor region 23 of the emitter region 17 from the third island 27g including the second semiconductor region 25 of the collector region 19 to insulate the emitter region 17 from the collector region 19. The first segmentation groove 27c and the second segmentation groove 27d extend across the ridge structure RDG in the direction of the second axis Ax2 to segment the semiconductor region (segmented structure 27) on the active region 15 of the semiconductor mesa MS into the second island 27f, the first island 27e, and the third island 27g. Specifically, the second island 27f, the first segmentation groove 27c, the first island 27e, the second segmentation groove 27d, and the third island 27g are arranged in sequence in the direction of the third axis Ax3. In this example, the first electrode 31a is in contact with the top surface of the first island 27e. The second electrode 31b is in contact with the top surface of the second island 27f (and the third island 27g). The second island 27f ends at the upper edge of the third side surface 15f. The third island 27g ends at the upper edge of the fourth side surface 15g. Specifically, the ridge structure RDG includes portions covering the first portion M1S and the second portion M2S (and the fourth portion M4S).

One end surface RDG1E of the waveguide structure including the semiconductor mesa MS (second portion M2S) and the ridge structure RDG includes the end surface of the second island 27f (the end surfaces of the collector region 19 and the contact layer 28a) and the end surface of the active region 15. The other end surface RDG2E of the waveguide structure including the semiconductor mesa MS (fourth portion M4S) and the ridge structure RDG includes the end surface of the third island 27g (the end surfaces of the collector region 19 and the contact layer 28a) and the end surface of the active region 15.

An insulating coating 37 covers the side and top surfaces of the active region 15, the first semiconductor region 23, and the second semiconductor regions 25 and the side and bottom surfaces of the first segmentation groove 27c and the second segmentation groove 27d. The insulating coating 37 has a first opening 37a above the top surface of the first island 27e and a second opening 37b above each of the top surfaces of the second island 27f and the third island 27g. The first electrode 31a is electrically connected to the first semiconductor region 23 through the first opening 37a. Specifically, the first electrode 31a is in contact with the contact layer 28a on the first semiconductor region 23. The second electrodes 31b are electrically connected to the second semiconductor regions 25 through the second openings 37b and are in contact with the contact layer 28a on the second semiconductor regions 25.

### Second Structure

A semiconductor laser 11b (11) will now be described with reference to FIGS. 2A to 2C. In the semiconductor laser 11b, the semiconductor mesa MS extends from one end toward the other end of the semiconductor laser 11b along the principal surface 13a of the substrate 13 in the direction of the waveguide axis (third axis Ax3). The semiconductor mesa MS ends at a position away from the other end toward the inside thereof. An end surface MSE of the semiconductor mesa MS includes the third side surface 15f of the active region 15. The position of the third side surface 15f of the active region 15 is shifted backward from the other end of the semiconductor laser 11b toward the inside thereof. The ridge structure RDG extends from one end toward the other end of the semiconductor laser 11b along the semiconductor mesa MS in the direction of the waveguide axis (third axis Ax3). The ridge structure RDG ends at a position away from the end surface MSE of the semiconductor mesa MS and the other end of the semiconductor laser 11b toward the inside thereof. An end surface RDGE of the ridge structure RDG is located above the first side surface 15b, the second side surface 15c, and the top surface 15d of the active region 15. The position of the end surface RDGE of the ridge structure RDG is shifted backward from the end surface MSE of the semiconductor mesa MS and the other end of the semiconductor laser 11b toward the inside thereof.

The collector region 19 includes a metal electrode 33. The metal electrode 33 extends in the direction of the first axis Ax1 on the third side surface 15f of the active region 15. The metal electrode 33 and the active region 15 are arranged in the direction of the waveguide axis (third axis Ax3) above the principal surface 13a of the substrate 13. The metal electrode 33 is disposed on the third side surface 15f of the active region 15. The metal electrode 33 is electrically connected to the third side surface 15f of the active region 15. In this example, the metal electrode 33 extends from the third side surface 15f of the active region 15 over the semiconductor region above the first area 13b and is in contact with the semiconductor region above the first area 13b. The semiconductor region (cladding layer 29) above the first area 13b is formed of a semi-insulating semiconductor. By shifting the position of the end surface RDGE backward from the end surface MSE of the semiconductor mesa MS, the metal electrode 33 may be separated from the emitter region 17.

The emitter region 17 is disposed on the top surface 15d of the active region 15 above the principal surface 13a of the substrate 13. Specifically, the first semiconductor region 23 of the emitter region 17 is in contact with the first side surface 15b, the second side surface 15c, and the top surface 15d of the active region 15 in the first portion M1S of the semiconductor mesa MS and extends in the direction of the waveguide axis. The first semiconductor region 23 of the emitter region 17 is not disposed on the active region 15 in the second portion M2S of the semiconductor mesa MS. The second portion M2S of the semiconductor mesa MS is provided in order to separate the emitter region 17 from the collector region 19. The emitter region 17 includes one or a plurality of semiconductor layers. The metal electrode 33 is disposed on the third side surface 15f of the active region 15 above the first area 13b. The carriers supplied from the active region 15 to the metal electrode 33 are of the same conductivity type as those supplied from the semiconductor forming the emitter region 17 to the active region 15. Thus, the semiconductor laser 11b utilizes unipolar carriers.

In the semiconductor laser 11b, the first semiconductor region 23 is of the first conductivity type. The active region 15 generates light by utilizing intersubband transitions of unipolar carriers (electrons or holes). The first semiconductor region 23 supplies carriers to the active region 15 through the top surface 15d of the active region 15. As carriers are injected from the first side surface 15b, the second side surface 15c, and the top surface 15d of the active region 15 into the active region 15, the carriers injected from the first semiconductor region 23 spread over the stack of quantum well structures 21 arranged in the direction of the first axis Ax1. The carriers in the individual quantum well structures 21 travel in the in-plane direction of the quantum wells while generating light through optical transitions. The carriers that have undergone transitions flow through the third side surface 15f of the active region 15 into the metal electrode 33 that extends in the direction of the first axis Ax1.

The active region 15 and the emitter region 17 extend in the direction of the third axis Ax3 above the principal surface 13a of the substrate 13. The metal electrode 33 extends along the third side surface 15f of the active region 15 in the direction of the second axis Ax2 and covers the third side surface 15f of the active region 15. The emitter region 17 is in contact with the top surface 15d of the active region 15 and supplies carriers of the first conductivity type (electrons or holes) to the active region 15. The metal electrode 33 is in contact with the third side surface 15f of the active region 15 and receives carriers of the first conductivity type (the carriers mentioned above) from the active region 15. The metal electrode 33 reflects light propagating through the waveguide in the active region 15. The light propagating through the waveguide is emitted from the fourth side surface 15g of the active region 15.

Structure of Semiconductor Laser 11 Having First or Second Structure

### Substrate 13: InP

Active region 15: 50-period superlattice structure composed of units of undoped AlInAs/undoped InGaAs/undoped AlInAs/undoped InGaAs
Width of semiconductor mesa MS: 10 μm
Height of semiconductor mesa MS: 1 μm
Thickness of core layer of active region 15: 0.8 μm
First semiconductor region 23: Si-doped InP/undoped AlInAs, Si-doped InP/Si-doped AlGaInAs/undoped AlInAs, or Si-doped InP/undoped AlGaPSb multilayer structure
Width of first semiconductor region 23 (width of ridge structure RDG): 8 μm
Thickness of first semiconductor region 23: 2 μm
Second semiconductor region 25: Si-doped InP/Si-doped GaInAs or Si-doped InP/Si-doped GaInAsP/Si-doped GaInAs multilayer structure
Width of second semiconductor region 25 (width of ridge structure RDG): 8 μm
Thickness of second semiconductor region 25: 2 μm
Contact layer 28a: 0.1 μm
Cladding layer 29 (lower current-blocking layer): semi-insulating InP, 0.2 μm thick
Metal electrode 33: Ti/Pt/Au (titanium/platinum/gold)

The semiconductor laser 11b has the first electrode 31a disposed on the emitter region 17 and the second electrode 31b connected to the collector region 19. The first electrode 31a and the metal electrode 33 are in ohmic contact with the first-conductivity-type semiconductor forming the emitter region 17 and the first-conductivity-type semiconductor forming the active region 15, respectively. The metal electrode 33 is connected to the second electrode 31b.

### Third Structure

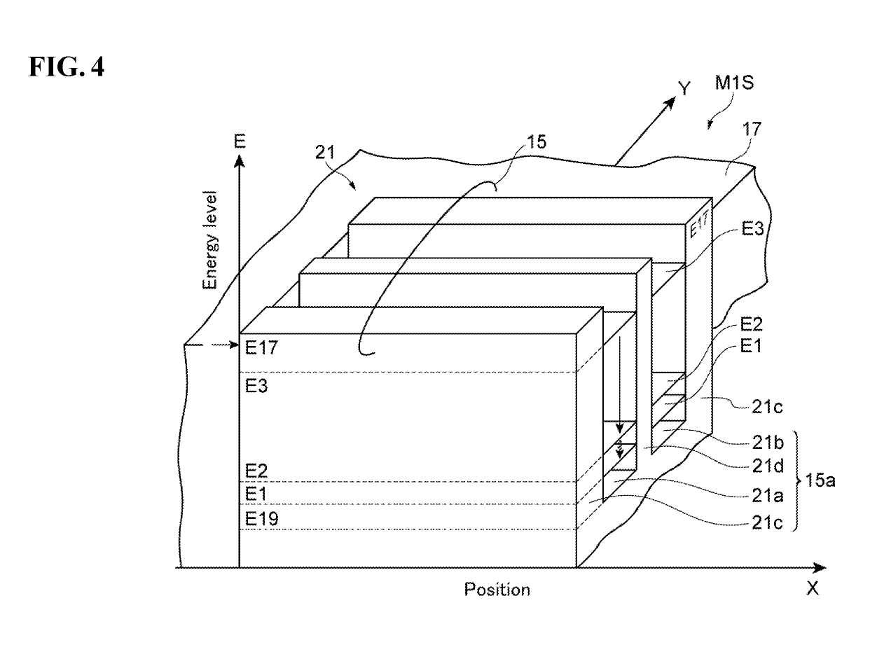

If necessary, in the first and second structures, the first semiconductor region 23 of the emitter region 17 may include a first semiconductor layer 33a in contact with the top surface 15d (and the first side surface 15b and second side surface 15c) of the active region 15 and a second semiconductor layer 33b disposed on the first semiconductor layer 33a. As shown in FIG. 4, the first semiconductor layer 33a includes a semiconductor having a conduction band energy (E17) higher than (higher in the potential direction depending on the carrier polarity) or equal to the upper energy level E3. The second semiconductor layer 33b includes a semiconductor having a refractive index lower than the equivalent refractive index of the active region 15. The conduction band energy level of the first semiconductor layer 33a allows carriers to be injected from the emitter region 17 to the upper energy level E3 of the active region 15 without requiring a large external bias.

The semiconductor laser 11a has the first electrode 31a disposed on the emitter region 17 and the second electrode 31b disposed on the collector region 19. The first electrode 31a and the second electrode 31b are in ohmic contact with the first-conductivity-type semiconductor forming the emitter region 17 and the first-conductivity-type semiconductor forming the collector region 19, respectively.

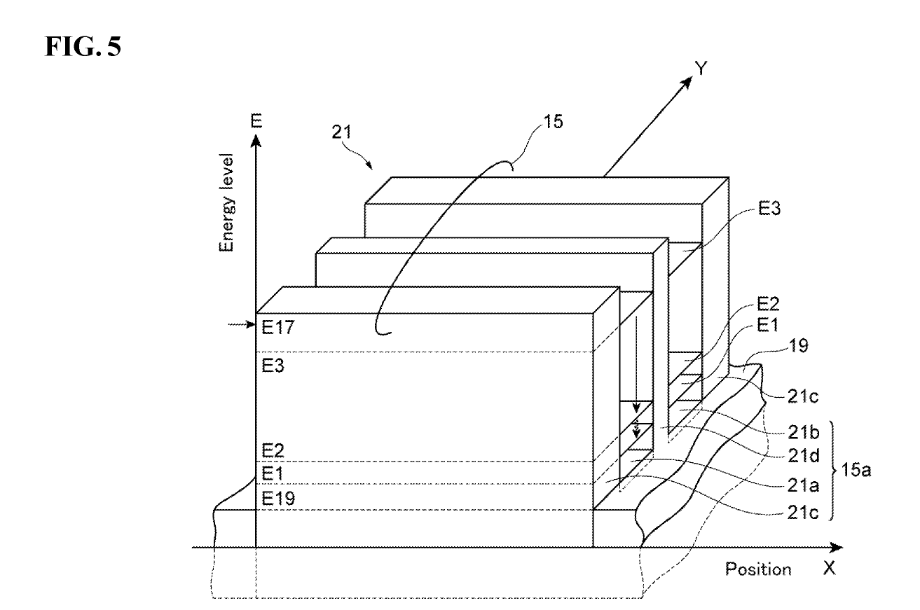

If necessary, in the first structure, the second semiconductor region 25 of the collector region 19 may include a third semiconductor layer 35a in contact with the first side surface 15b and second side surface 15c (and the top surface 15d) of the active region 15 and a fourth semiconductor layer 35b disposed on the third semiconductor layer 35a. As shown in FIG. 5, the third semiconductor layer 35a includes a semiconductor having a conduction band energy (E19) lower than or equal to the lower energy level E2, preferably the relaxation energy level E1. The fourth semiconductor layer 35b includes a semiconductor having a refractive index lower than the equivalent refractive index of the active region 15. The conduction band energy level of the third semiconductor layer 35a allows carriers to be extracted from the energy level of the active region 15 into the collector region 19 without requiring a large external bias.

### Example 1

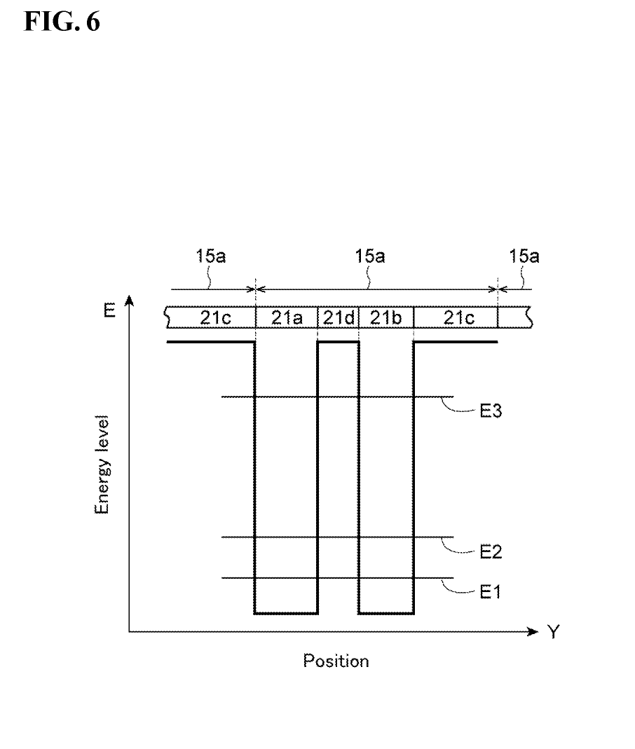

The quantum well structures will now be described with reference to FIG. 6. In the following description, electrons function as carriers. Similarly, holes may function as carriers. To increase the probability of transitions from the upper energy level E3 to the lower energy level E2, it is preferred to decrease the carrier density at the lower energy level E2. The decrease of the carrier density at the lower energy level E2 is realized by quickly transiting carriers from the lower energy level E2 to a relaxation energy level E1. Each of the quantum well structure 21 includes, for example, a plurality of (e.g., two) well layers (21a and 21b) and one or a plurality of barrier layers provided between these well layers. The barrier layer 21d has a thickness smaller than that of the barrier layer 21c. Thus, the wave functions of electrons in the well layers (21a and 21b) extend through the barrier layer 21d into the well layers (21b and 21a) and are coupled to each other. This structure is referred to as “coupled quantum wells”. The coupled quantum wells have a symmetrical well structure with respect to the centerline (the center in the thickness direction) of the barrier layer 21d. This structure provides the relaxation energy level E1 that is lower than the lower energy level E2. A difference of energy level between the lower energy level E2 and the relaxation energy level E1 corresponds approximately to the longitudinal optical (LO) phonon energy. Thus, electrons that have undergone radiative transitions from the upper energy level E3 to the lower energy level E2 may transition rapidly to the relaxation energy level E1 through phonon scattering (resonance). The coupled quantum wells also increase the overlap between the wave functions of the upper energy level E3 and the lower energy level E2 and thus increase the probability of radiative transitions, thereby increasing the laser gain.

### Specific Example of Coupled Quantum Wells

Well layers/barrier layers: undoped InGaAs/undoped AlInAs
Thickness of well layer (21a): 4 nm
Thickness of inner barrier layer (21d): 2 nm
Thickness of well layer (21b): 4 nm
Thickness of outer barrier layer (21c): 10 nm
Energy difference for oscillation (energy difference between upper energy level E3 and lower energy level E2): 270 meV (oscillation wavelength: 4.6 μm)
Optical gain: 96 cm⁻¹/period
Epop (energy difference between lower energy level E2 and relaxation energy level E1): 35.6 meV
Substrate 13: InP substrate
The active region does not require injection layers, which are always included in conventional quantum cascade semiconductor lasers. This results in a greater flexibility in designing the quantum well structures in the quantum cascade semiconductor lasers. In addition, for example, a strain-compensated superlattice structure is used. In the strain-compensated superlattice structure, a tensile stress is introduced into the barrier layers and a compressive stress is introduced into the well layers, for example. By allowing the tensile and compressive stresses to substantially cancel each other out over the entire quantum well structures, a large conduction band gap difference (deep quantum well) can be achieved while good crystallinity is maintained. This results in improved temperature characteristics with reduced carrier leakage and a broader oscillation wavelength range.

### Example 2

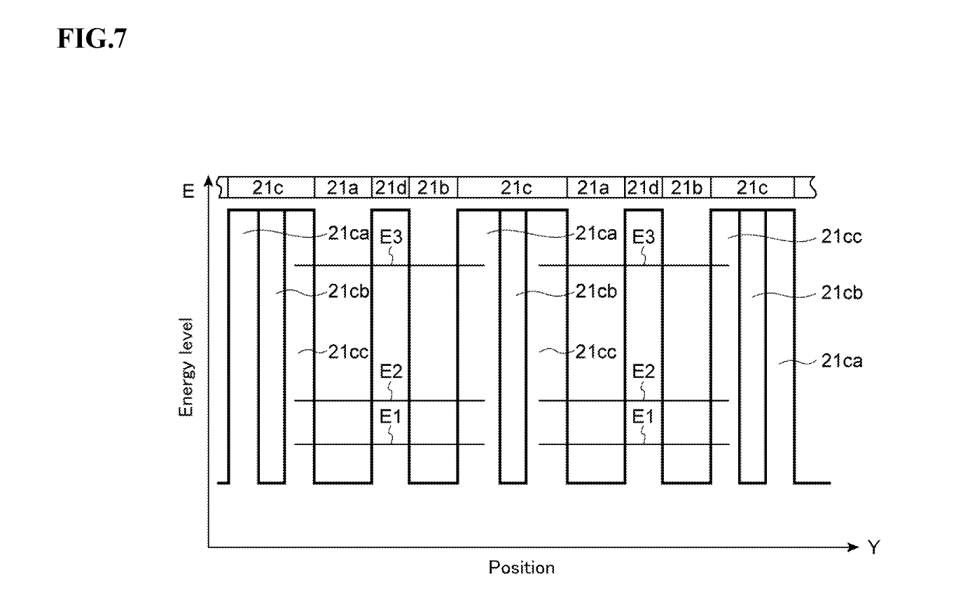

As shown in FIG. 7, at least a portion of a barrier layer in each quantum well structure may be doped with a dopant of the same polarity as the carriers. This doping improves the efficiency of injection into both well layers. For example, a 10 nm thick AlInAs barrier layer may include undoped thin region 21ca and 21cc adjacent to the well layers and a doped thin region 21cb therebetween. A doping concentration of about 10¹⁷ cm⁻³ or less is preferred to reduce optical loss due to free carrier absorption. This doped thin region improves the conductivity of the stacked semiconductor layer in the active region in the in-plane direction. As a result, carriers may be supplied to the well layers at positions apart from the emitter region in the in-plane direction.

### Example 3

In the semiconductor laser 11 according to this embodiment, carriers are injected from the emitter region 17 into the quantum well structures 21 in the active region 15 in the direction of the first axis Ax1 and are thereby supplied to each quantum well structure 21. The carriers in the quantum well structures 21 are transported in a direction parallel to the in-plane direction of the quantum well layers. The electron distribution in the active region is estimated by simulation. To estimate carrier transport in the in-plane direction, the device models used for numerical experimentation are shown below.

Resonator length L1: 500 μm
Opening width W of emitter region: 10 μm
One-side mesa width from center of opening in emitter region on active region in mesa structure to one upper edge of top surface of mesa: 10 μm
One-side mesa width from center of opening in emitter region on active region in mesa structure to other upper edge of top surface of mesa: 10, 20, 50, and 100 μm
Electrons drift through the opening in the emitter region in an electric field and are injected into the active region.
Active region: AlInAs/GaInAs multiple quantum well structure

| | Electrical | Electrical | Ratio of electrical |
|---|---|---|---|
| | conductivity in | conductivity in | conductivity in perpendicular |
| | perpendicular | transverse | direction to electrical |
| Model | direction | direction | conductivity in |
| name | (S/m) | (S/m) | transverse direction |
| First | 4.3E−5 | 1.7E−2 | 2.53E−3 |
| model | | | |
| Second | 1.5E−5 | 1.7E−2 | 8.74E−4 |
| model | | | |
| Third | 1.7E−6 | 1.7E−2 | 9.84E−5 |
| model | | | |

The notation “2.53E−3” refers to 2.53 × 10⁻³.

The ratio of the electrical conductivity in the perpendicular direction to the electrical conductivity in the transverse direction is the electrical conductivity in the perpendicular direction divided by the electrical conductivity in the transverse direction.

### Current Density in Transverse Direction

The calculation results of distribution of the electron current density using a model with a mesa width of 100 μm show that the electron current density in the transverse direction increases with increasing ratio of the electrical conductivity in the perpendicular direction to the electrical conductivity in the transverse direction of the quantum wells. In addition, the calculation results using a model with a mesa width of 20 μm show that the electron current density at the collector electrode does not vary in the depth direction even when the electrical conductivity ratio varies in the range from 2.53E-3 to 9.84E-5.

### Current Density in Perpendicular Direction

The calculation results of distribution of the electron current density using a model with a mesa width of 100 μm show that the electron current density in the perpendicular direction is concentrated directly below the emitter electrode. In addition, the calculation results using a model with a mesa width of 20 μm show that the electron current density on the downstream side decreases with increasing ratio of the electrical conductivity in the perpendicular direction to the electrical conductivity in the transverse direction of the quantum wells. In this case, however, electrons are sufficiently distributed on the downstream side even when the electrical conductivity ratio varies in the range from 2.53E-3 to 9.84E-5.

In the semiconductor laser 11 according to this embodiment, the carriers in the quantum well structures 21 are transported in a direction parallel to the in-plane direction of the quantum well layers. At this point of view, the semiconductor laser 11 differs from conventional quantum cascade semiconductor lasers. In the semiconductor laser 11 according to this embodiment, the carriers in the quantum well structures 21 do not pass through heterobarriers that are provided in a direction perpendicular to the in-plane direction of the quantum well layers. Therefore, the semiconductor laser 11 according to this embodiment operates at low voltage. The quantum well structures 21, which are connected in parallel, provide a large laser gain without an increase in operating voltage due to the stacking of the quantum well structures 21. In addition, the semiconductor laser 11 according to this embodiment does not exhibit loss due to tunneling transport as in quantum cascade semiconductor lasers. This results in a significant reduction in power consumption as compared to conventional quantum cascade semiconductor lasers.

The structure according to this embodiment does not include injection layers that are stacked in the direction in which current flows. Conventional quantum cascade semiconductor lasers usually include the injection layers between the quantum well structures. As a result, the operating voltage is reduced for the laser device according to this embodiment. Specifically, the voltage drop between the two electrodes on the current injection (emitter) and extraction (collector) sides is the sum of the voltage drop associated with the energy of the oscillation wavelength and the voltage drop due to the series resistance of the device. To increase the optical gain, a stack of unit cells of quantum well structures is employed in the active region. However, there is no increase in voltage with increasing number of unit cells because of the operating mechanism of the structure according to this embodiment. This results in a significant reduction in the operating voltage of the laser device.

Conventional quantum cascade semiconductor lasers use cascade stacking of unit cells for light emission and carrier injection in the stacking direction. Thus, conventional quantum cascade semiconductor lasers exhibit carrier loss due to carrier injection layers. In contrast, the device structure according to this embodiment does not require carrier injection layers and thus does not exhibit carrier loss due to carrier injection layers. The device structure according to this embodiment offers a greater flexibility in designing the multilayer structure of the active region. This results in improvements in device characteristics. For example, a lower threshold current, a lower operating voltage, and lower power consumption are obtained for the device structure according to this embodiment as compared to the conventional quantum cascade semiconductor lasers. In addition, since the device according to this embodiment has a planar structure without a large step, electrodes may be provided on the top surface of a wafer. This allows function enhancements such as integration with other devices and assembly into arrays. Furthermore, the absence of carrier injection layers results in a reduction in the epitaxial layer thickness of the active region. In addition, optical characteristics may be evaluated in a nondestructive manner by using techniques such as photoluminescence after epitaxial growth. This contributes to reductions in manufacturing time and cost.

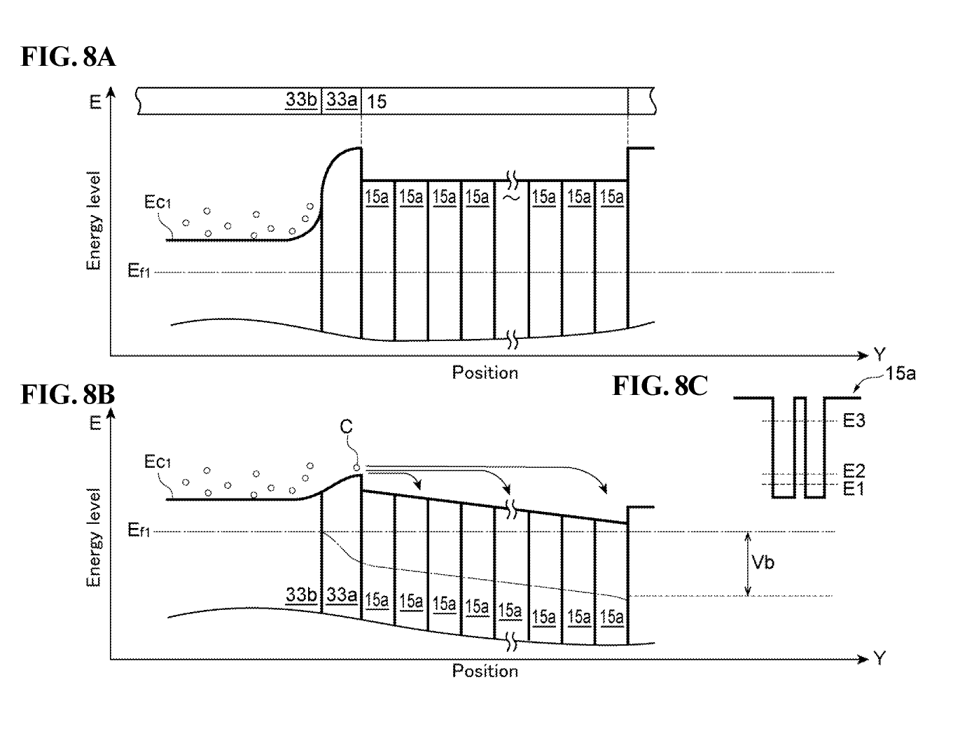

The supply of carriers from the emitter region into the active region will now be described with reference to FIGS. 8A, 8B, and 8C. FIG. 8A schematically shows the band structure of the emitter region 17 and the active region 15 under no bias. FIG. 8B schematically shows the band structure of the emitter region 17 and the active region 15 under a forward external bias. In FIGS. 8A and 8B, the arrangement of the unit cells 15a is shown to indicate that the active region 15 has a superlattice structure. The superlattice structure in the arrangement of the unit cells 15a includes a periodically alternating arrangement of well layers and barrier layers. Each unit cell 15a is shown in FIG. 8C. In FIGS. 8A and 8B, “E_{f1}” indicates the Fermi level or quasi Fermi level, and “E_{c1}” indicates the conduction band. The conduction band level of the first semiconductor layer 33a is higher than the conduction band level of the second semiconductor layer 33b.

### Structure of Emitter Region

First semiconductor layer 33a: undoped AlGaPSb, 20 nm thick
Second semiconductor layer 33b: Si-doped InP, 200 nm thick

As shown in FIG. 8B, an external bias is applied to the semiconductor laser 11 to reduce the heterobarrier between the first semiconductor layer 33a and the second semiconductor layer 33b. As the heterobarrier is reduced, high-energy carriers C (electrons) are injected from the emitter region 17 into the superlattice structure of the active region 15 across the heterobarrier by thermal emission. The injected carriers C are attracted by an electric field and drift or diffuse through the active region 15. Simultaneously, the injected carriers C lose their energy at the levels within the conduction band that correspond to the energies of the individual carriers C, and fall into various unit cells 15a. The carriers C drift through the unit cells 15a toward the collector regions 19 while generating light through optical transitions from the higher energy level (E3) to the lower energy level (E2). The carriers C at the energy level (E2) relax rapidly to the even lower energy level (E1).

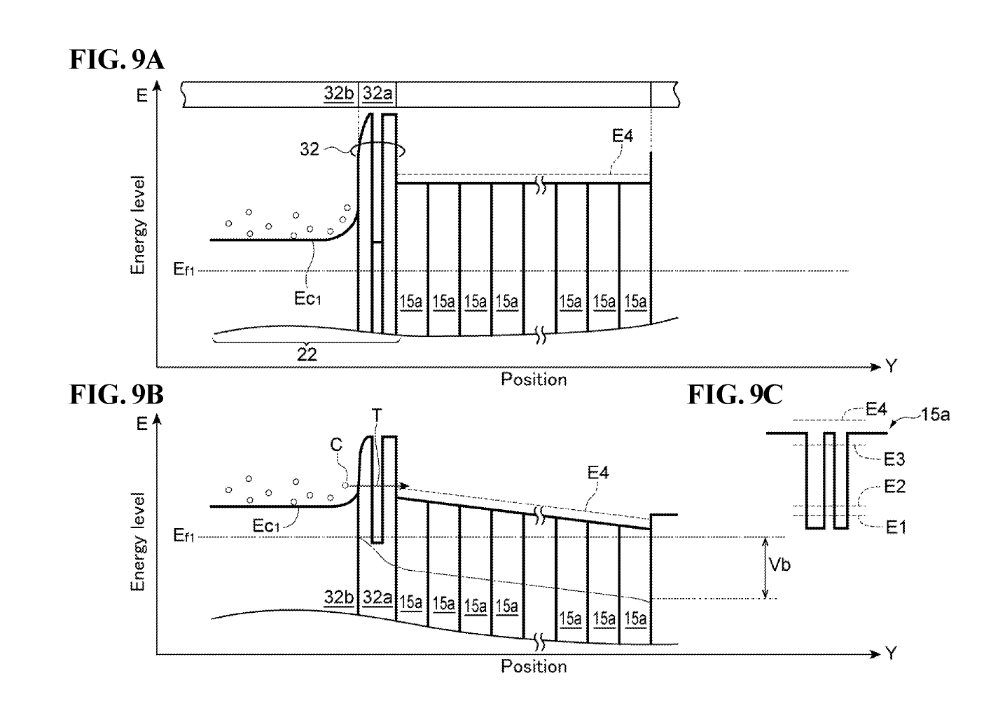

The supply of carriers from the emitter region into the active region will now be described with reference to FIGS. 9A, 9B, and 9C. FIG. 9A schematically shows the band structure of an emitter region 22 and the active region 15 under no bias. FIG. 9B schematically shows the band structure of the emitter region 22 and the active region 15 under a forward external bias. In FIGS. 9A and 9B, the arrangement of the unit cells 15a is shown to indicate that the active region 15 has a superlattice structure. The superlattice structure in the unit cells 15a includes well layers and barrier layers that are stacked alternately and periodically. Each unit cell 15a is shown in FIG. 9C. In FIG. 9C, a level E4 in the active region 15 is also shown. In FIGS. 9A and 9B, “E_{f1}” indicates the Fermi level or quasi Fermi level, and “E_{c1}” indicates the conduction band. The emitter region 22 includes a first semiconductor layer 32a including a tunneling structure 32 adjacent to the top surface of the active region 15.

### Structure of Emitter Region 22

First semiconductor layer 32a: undoped AlGaPSb/GaInAs
Second semiconductor layer 32b: Si-doped InP, 200 nm thick
The tunneling structure 32 has, for example, the following structure: AlGaPSb (5 nm thick)/GaInAs (2 nm thick)/AlGaPSb (5 nm thick)

As shown in FIG. 9B, an external bias is applied to the semiconductor laser 11 to reduce the heterobarrier between the first semiconductor layer 32a and the second semiconductor layer 32b. As the conduction band level of the second semiconductor layer 32b approaches the discrete energy level (E4) in the active region 15, the carriers C are injected from the conduction band of the second semiconductor layer 32b to the energy level (E4) of the superlattice structure of the active region 15 by tunneling T through the tunneling structure 32. The injected carriers C are attracted by an electric field and drift or diffuse through the active region 15. Simultaneously, the injected carriers C lose their energy at the levels within the conduction band that correspond to the energies of the individual carriers C (e.g., the level E4), and fall into various unit cells 15a. The carriers C drift through the unit cells 15a toward the collector regions 19 while generating light through optical transitions from the higher energy level (E3) to the lower energy level (E2). The carriers C at the energy level (E2) relax rapidly to the even lower energy level (E1).

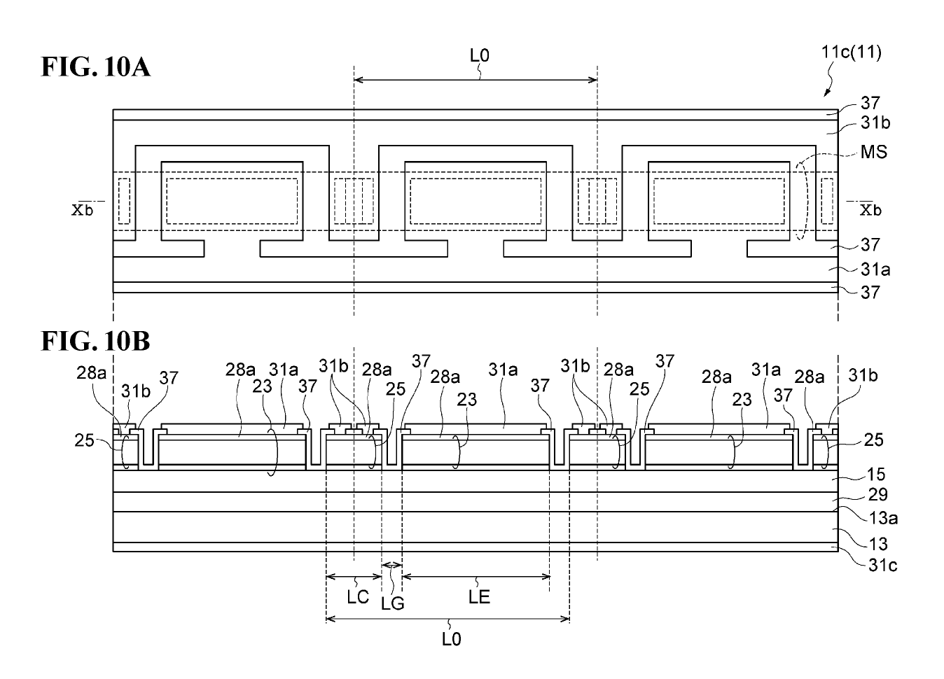

FIGS. 10A and 10B schematically shows the semiconductor laser according to this embodiment. FIG. 10A is a plan view showing the semiconductor laser. FIG. 10B is a sectional view taken along line Xb-Xb in FIG. 10A. A semiconductor laser 11c (11) has a structure including separate electrodes arranged in the resonator direction. In this structure, the first semiconductor region 23 of the emitter region 17 and the second semiconductor region 25 of the collector region 19 are alternately arranged. This structure can increase the optical output. The semiconductor laser 11c, in which the alternating arrangement of the first semiconductor region 23 and the second semiconductor region 25 has a period (L0) of RMD/2 (where RMD is the oscillation wavelength), has a gain-coupled distributed feedback structure and thus provides improved single-mode characteristics. The active region 15 periodically receives injection of carriers from the emitter region 17 in the optical resonator direction.

The semiconductor laser 11c (11) includes a periodic arrangement of basic structures, each including the first semiconductor region 23 of the emitter region 17 and the second semiconductor region 25 of the collector region 19.

### Example Structure of Semiconductor Laser 11c

Oscillation wavelength (RMD): 6 μm
L0: 10 μm, as roughly calculated from n×6/(3×2) (where n=10 and equivalent refractive index of semiconductor=3)
Length LE of emitter region 17: 4 μm
Length LC of collector region 19: 3 μm
Width LG of segmentation grooves: 1.5 μm
Single-mode conditions: L0=n×RMD/2
The semiconductor laser 11c includes three connected unit structures (first structures), each having a length of L0. An increased number of connected unit structures results in an increased gain (increased optical output) and improved single-mode characteristics.

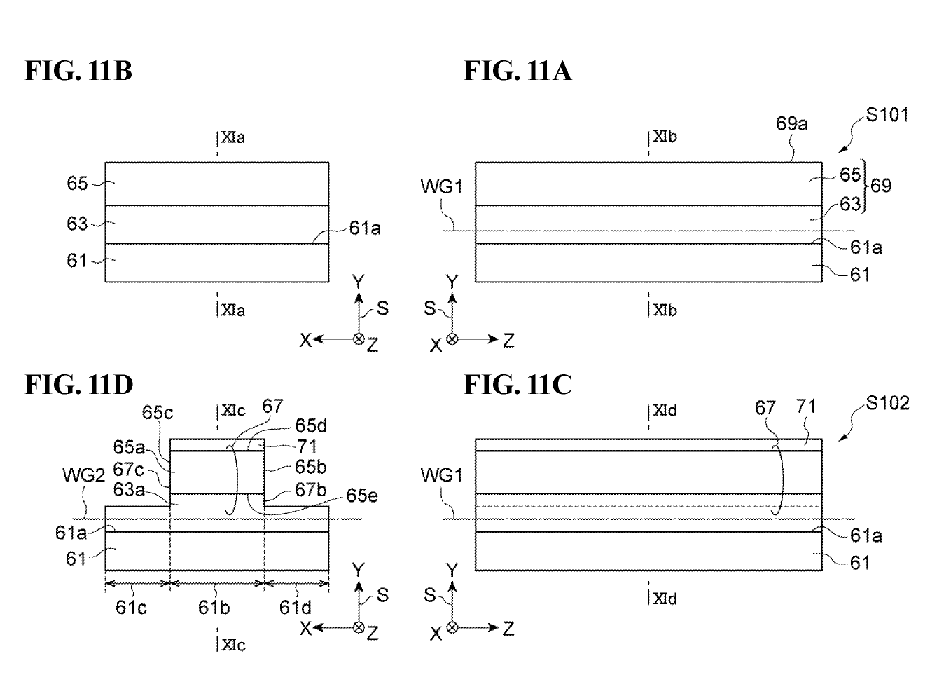

A method of manufacture will now be described in outline with reference to FIGS. 11A to 11D, 12A to 12D, and 13A to 13D. In step S101, an epitaxial wafer is formed. FIG. 11A is a sectional view taken along the waveguide axis WG1. FIG. 11B is a sectional view taken along line XIb-XIb in FIG. 11A. FIG. 11A is a sectional view taken along line XIa-XIa in FIG. 11B. As shown in FIGS. 11A and 11B, a Si-doped InP substrate 61 is provided. Crystal growth is performed, for example, by using a molecular beam epitaxy (MBE) method or a metal-organic vapor phase epitaxy (MOVPE) method. An InP layer 63 for forming a lower cladding layer is grown on a principal surface 61a of the InP substrate 61. For example, the InP layer 63 is a Si-doped InP film. A superlattice structure 65 for forming an active region including a stack of unit cells having, for example, the four-layer structure described above is grown on the InP layer 63. By this step, a lower stacked semiconductor layer 69 is formed.

In step S102, a semiconductor mesa for forming the waveguide structure including a laser cavity is formed. FIG. 11C is a sectional view taken along the waveguide axis WG1. FIG. 11D is a sectional view taken along line XId-XId in FIG. 11C. FIG. 11C is a sectional view taken along line XIc-XIc in FIG. 11D. As shown in FIGS. 11C and 11D, a first SiN mask 71 for forming the semiconductor mesa is formed on a principal surface 69a of the lower stacked semiconductor layer 69 by using a photolithography method and an etching method. The lower stacked semiconductor layer 69 is etched through the first SiN mask 71 to form a stripe-shaped mesa 67 extending in the direction of the Z-axis. The stripe-shaped mesa 67 includes a lower cladding layer 63a and a superlattice structure 65a.

After the stripe-shaped mesa 67 is formed, the superlattice structure 65a has a first side surface 65b and a second side surface 65c. In addition to the first side surface 65b and the second side surface 65c, the superlattice structure 65a has a top surface 65d and a bottom surface 65e. The stripe-shaped mesa 67 is formed above a first area 61b of the principal surface 61a. The lower stacked semiconductor layer 69 is etched above a second area 61c and a third area 61d of the principal surface 61a. The first area 61b and the second area 61c extend in the direction of the waveguide axis WG1 (the Z-axis of the Cartesian coordinate system S) and are arranged in the direction of an intersecting axis WG2 (the X-axis of the Cartesian coordinate system S) intersecting the waveguide axis WG1. The first area 61b is located between the second area 61c and the third area 61d. The stripe-shaped mesa 67 has a first side surface 67b and a second side surface 67c. The first side surface 67b and the second side surface 67c (and the top and bottom surfaces) extend in the direction of the waveguide axis WG1. After the stripe-shaped mesa 67 is formed, the first SiN mask 71 is removed.

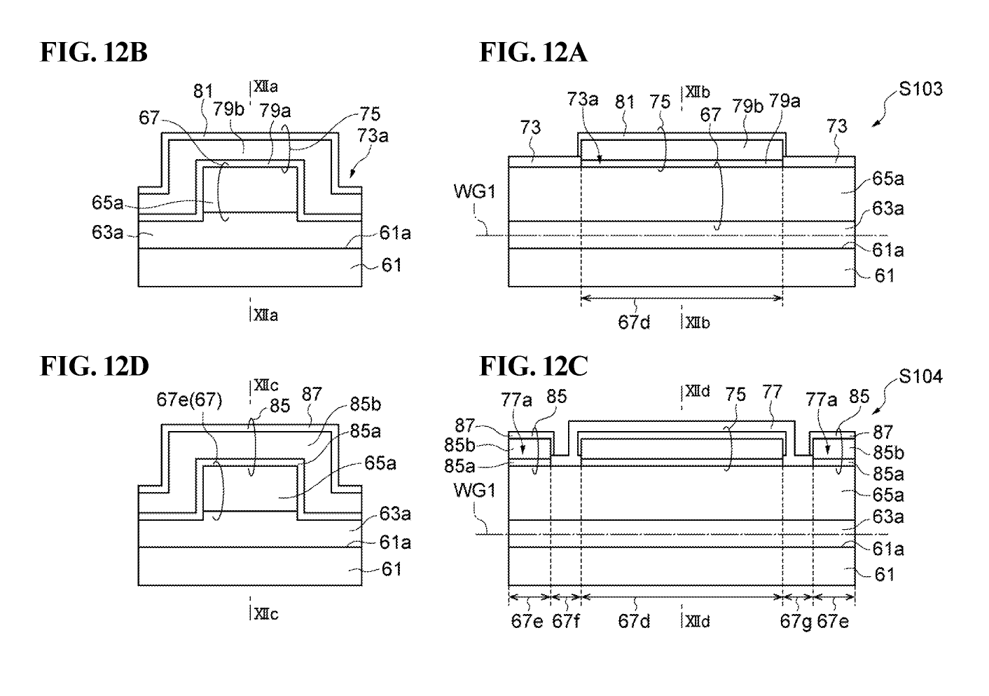

In step S103, regrowth for forming an emitter region and a contact layer is performed. In this example, regrowth for forming an emitter region is performed before regrowth for forming collector regions. However, regrowth for forming collector regions may be performed before regrowth for forming an emitter region. FIG. 12A is a sectional view taken along the waveguide axis WG1. FIG. 12B is a sectional view taken along line XIIb-XIIb in FIG. 12A. FIG. 12A is a sectional view taken along line XIIa-XIIa in FIG. 12B. As shown in FIGS. 12A and 12B, after the stripe-shaped mesa 67 is formed, a second SiN mask 73 for defining the emitter region is formed over the principal surface 61a of the InP substrate 61 by using a photolithography method and an etching method. The second SiN mask 73 has an opening 73a through which an emitter region may be formed on the top and side surfaces of a first portion 67d of the stripe-shaped mesa 67. After the second SiN mask 73 is formed, a Si-doped AlInAs layer 79a and a Si-doped InP layer 79b are selectively grown in sequence. A Si-doped InGaAs layer 81 for forming a contact layer is then grown on the Si-doped InP layer 79b. A first RDG semiconductor region 75 serving as an emitter region is formed on the top and side surfaces of the first portion 67d of the stripe-shaped mesa 67 and on the lower cladding layer 63a above the second area 61c and the third area 61d. The Si-doped AlInAs layer 79a preferably has a thickness sufficient to block tunneling conduction of electrons, for example, more than 10 nm. After the emitter region is selectively grown, the second SiN mask 73 is removed.

In step S104, regrowth for forming collector regions and a contact layer is performed. FIG. 12C is a sectional view taken along the waveguide axis WG1. FIG. 12D is a sectional view taken along line XIId-XIId in FIG. 12C. FIG. 12C is a sectional view taken along line XIIc-XIIc in FIG. 12D. As shown in FIGS. 12C and 12D, after the regrowth for forming the emitter region, a third SiN mask 77 for defining the collector regions is formed over the principal surface 61a of the InP substrate 61 by using a photolithography method and an etching method. The third SiN mask 77 has openings 77a through which collector regions may be formed on the top and side surfaces of second and fourth portions 67e of the stripe-shaped mesa 67. To form collector regions, after the third SiN mask 77 is formed, a Si-doped InGaAs layer 85a and a Si-doped InP layer 85b are selectively grown in sequence. A Si-doped InGaAs layer 87 for forming a contact layer is then grown on the Si-doped InP layer 85b. Second RDG semiconductor regions 85 serving as collector regions are formed on the top and side surfaces of the second and fourth portions 67e of the stripe-shaped mesa 67 and on the lower cladding layer 63a above the second area 61c and the third area 61d. Preferably, the Si-doped GaInAs layer 85a is relatively thin, for example, 10 to 50 nm thick. This is sufficient to allow optical confinement in the transverse direction and thereby stabilize the transverse mode of the semiconductor laser. After the collector regions are selectively grown, the third SiN mask 77 is removed to form a semiconductor product. The semiconductor product has the emitter region formed on the top and side surfaces of the first portion 67d of the stripe-shaped mesa 67 and the collector regions formed on the top and side surfaces of the second and fourth portions 67e of the stripe-shaped mesa 67. Neither the emitter region nor the collector regions are grown on the top and side surfaces of a third portion 67f and a fifth portion 67g of the stripe-shaped mesa 67. The third portion 67f and the fifth portion 67g of the stripe-shaped mesa 67 are formed to provide segmentation grooves for electrical insulation.

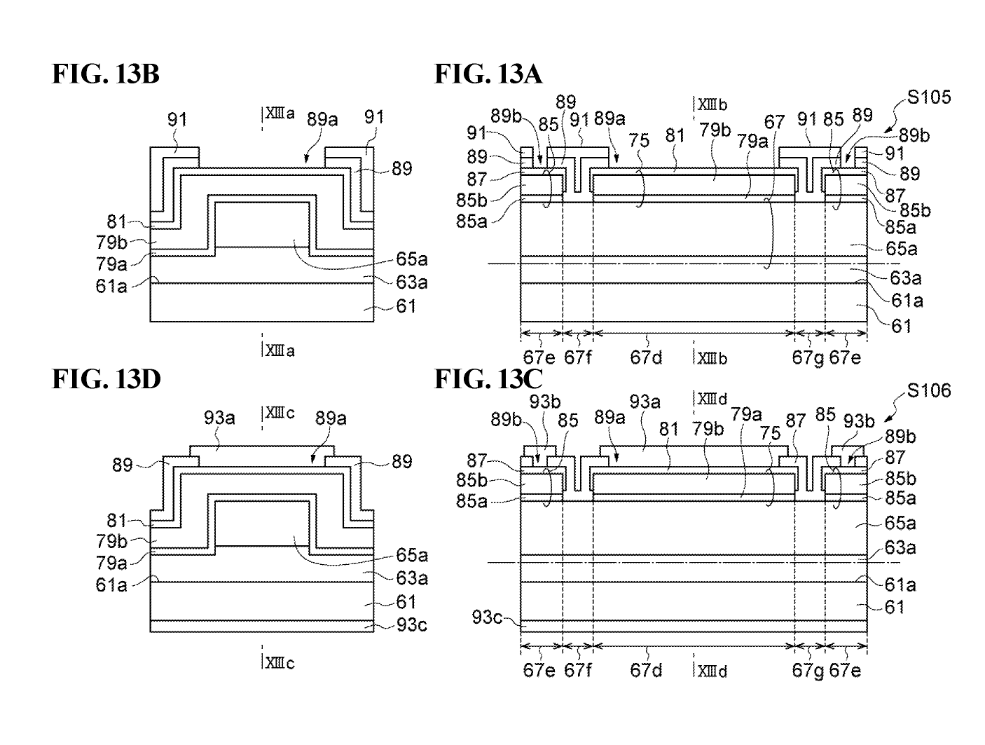

In step S105, a passivation film is formed. FIG. 13A is a sectional view taken along the waveguide axis WG1. FIG. 13B is a sectional view taken along line XIIIb-XIIIb in FIG. 13A. FIG. 13A is a sectional view taken along line XIIIa-XIIIa in FIG. 13B. As shown in FIGS. 13A and 13B, after the emitter region and the collector regions are formed, a protective film 89 having an emitter opening 89a and collector openings 89b is formed. For example, a SiN film is formed over the entire surface of the semiconductor product by chemical vapor deposition (CVD). A mask 91 is then formed on the SiN film by using a photolithography method. This mask 91 has the emitter opening 89a above the emitter region on the first portion 67d of the stripe-shaped mesa 67 and the collector openings 89b above the collector regions on the second and fourth portions 67e of the stripe-shaped mesa 67. The SiN film is processed by etching to obtain a SiN protective film 89. After the etching, the mask 91 is removed.

In step S106, electrodes are formed. FIG. 13C is a sectional view taken along the waveguide axis WG1. FIG. 13D is a sectional view taken along line XIIId-XIIId in FIG. 13C. FIG. 13C is a sectional view taken along line XIIIc-XIIIc in FIG. 13D. As shown in FIGS. 13C and 13D, after the protective film 89 is formed, an emitter electrode 93a and collector electrodes 93b are formed. For example, the emitter electrode 93a and the collector electrodes 93b are formed by forming a lift-off mask and then growing over the lift-off mask a metal film for forming the emitter electrode 93a and the collector electrodes 93b. The lift-off mask is removed to form the emitter electrode 93a and the collector electrodes 93b. If necessary, a back metal film 93c may be formed on the back surface of the InP substrate 61 after polishing. The thus-fabricated substrate product is cleaved to form a laser bar.

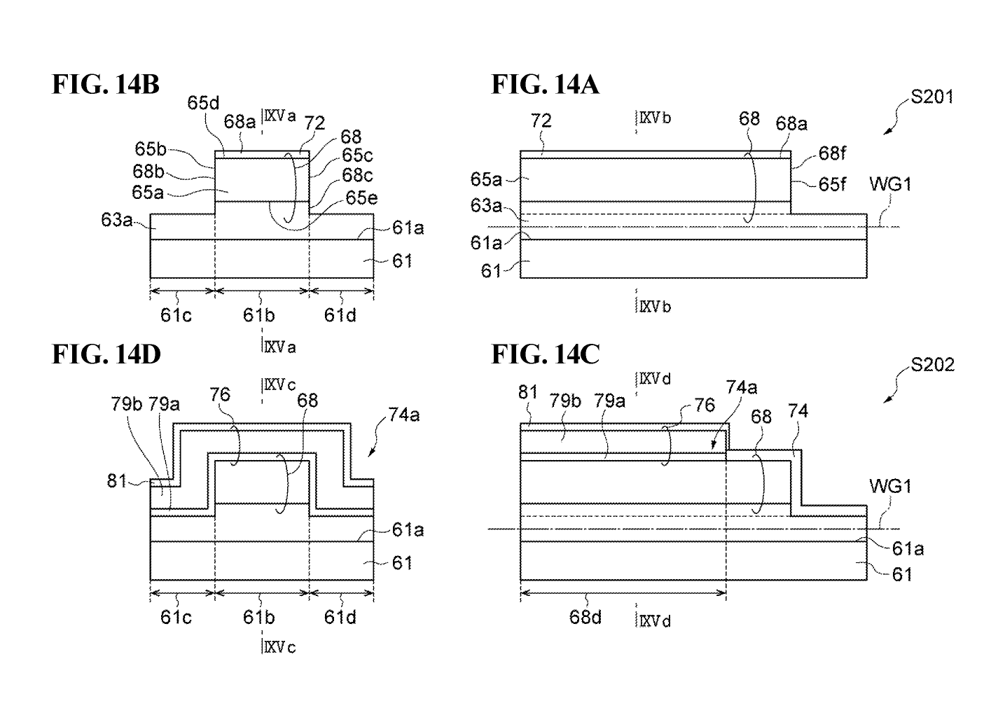

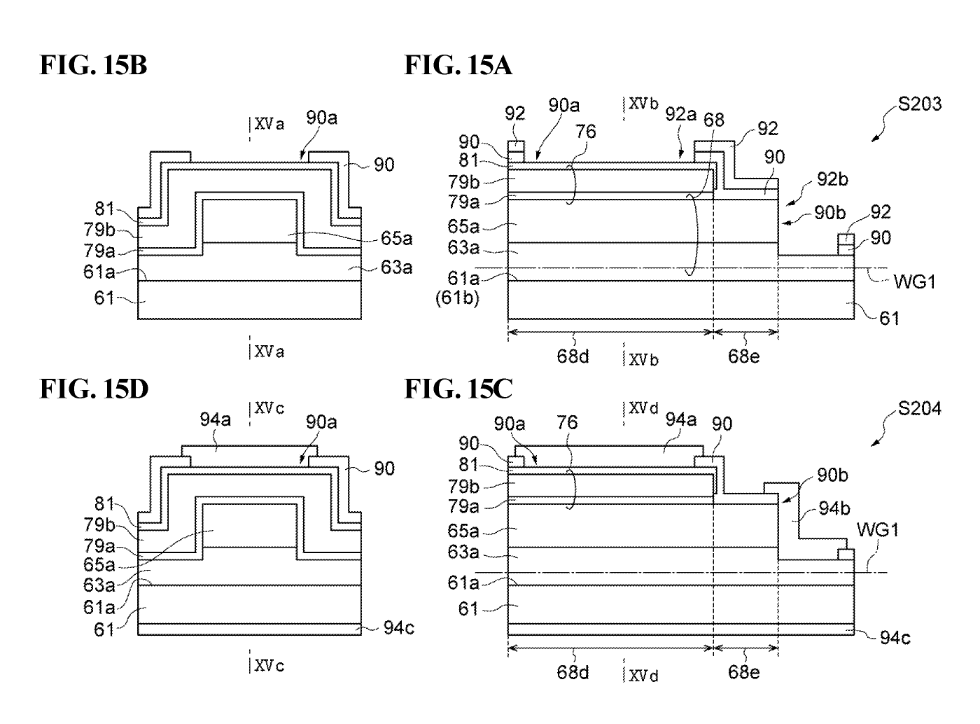

Another method of manufacture will now be described in outline with reference to FIGS. 14A to 14D and 15A to 15D.

After an epitaxial wafer is formed in step S201, a semiconductor mesa for forming a laser waveguide is formed in step S201. FIG. 14A is a sectional view taken along the waveguide axis WG1. FIG. 14B is a sectional view taken along line IXVb-IXVb in FIG. 14A. FIG. 14A is a sectional view taken along line IXVa-IXVa in FIG. 14B. As shown in FIGS. 14A and 14B, a first SiN mask 72 for forming a semiconductor mesa is formed on the principal surface 69a of the lower stacked semiconductor layer 69 by using a photolithography method and an etching method. The lower stacked semiconductor layer 69 is etched through the first SiN mask 72 to form a stripe-shaped mesa 68 extending in the direction of the Z-axis. The stripe-shaped mesa 68 includes a lower cladding layer 63a and a superlattice structure 65a. After the stripe-shaped mesa 68 is formed, the superlattice structure 65a has a first side surface 65b and a second side surface 65c. In addition to the first side surface 65b and the second side surface 65c, the superlattice structure 65a has a top surface 65d, a bottom surface 65e, and a third side surface 65f. During the formation of the semiconductor mesa, the lower stacked semiconductor layer 69 is etched above a second area 61c and a third area 61d of the principal surface 61a. The semiconductor mesa is formed above the first area 61b of the principal surface 61a. Specifically, the stripe-shaped mesa 68 has the lower stacked semiconductor layer 69 partially removed above the first area 61b. The stripe-shaped mesa 68 ends at a position away from a device region boundary. The superlattice structure 65a has the third side surface 65f The stripe-shaped mesa 68 has a side surface 68f. The stripe-shaped mesa 68 has a top surface 68a and a first side surface 68b and a second side surface 68c extending in the direction of the waveguide axis WG1. After the stripe-shaped mesa 68 is formed, the first SiN mask 72 is removed.

In step S202, regrowth for forming an emitter region is performed. FIG. 14C is a sectional view taken along the waveguide axis WG1. FIG. 14D is a sectional view taken along line IXVd-IXVd in FIG. 14C. FIG. 14C is a sectional view taken along line IXVc-IXVc in FIG. 14D. As shown in FIGS. 14C and 14D, after the stripe-shaped mesa 68 is formed, a second SiN mask 74 for defining the emitter region is formed over the principal surface 61a of the InP substrate 61 by using a photolithography method and an etching method. The second SiN mask 74 has an opening 74a through which an emitter region can be formed on the top and side surfaces of a first portion 68d of the stripe-shaped mesa 68. After the second SiN mask 74 is formed, a Si-doped AlInAs layer 79a and a Si-doped InP layer 79b are selectively grown in sequence. A Si-doped InGaAs layer 81 for forming a contact layer is then grown on the Si-doped InP layer 79b. A first RDG semiconductor region 76 serving as an emitter region is formed on the top and side surfaces of the first portion 68d of the stripe-shaped mesa 68 and on the lower cladding layer 63a above the second area 61c and the third area 61d. The Si-doped AlInAs layer 79a preferably has a thickness sufficient to block tunneling conduction of electrons, for example, more than 10 nm. After the emitter region is selectively grown, the second SiN mask 74 is removed.

In step S203, a passivation film is formed. FIG. 15A is a sectional view taken along the waveguide axis WG1. FIG. 15B is a sectional view taken along line XVb-XVb in FIG. 15A. FIG. 15A is a sectional view taken along line XVa-XVa in FIG. 15B. As shown in FIGS. 15A and 15B, after the emitter region is formed by regrowth, a protective film 90 having an emitter opening 90a and a collector opening 90b is formed. For example, a SiN film is formed over the entire surface of the semiconductor product by CVD. A mask 92 is then formed on the SiN film by using a photolithography method and an etching method. This mask 92 has the emitter opening 90a above the first portion 68d of the stripe-shaped mesa 68 and the collector opening 90b above the second portion 68e of the stripe-shaped mesa 68 and the InP lower cladding layer 63a above the first area 61b. The SiN film is processed by etching to obtain a SiN protective film 90. After the etching, the mask 92 is removed.

In step S204, electrodes are formed. FIG. 15C is a sectional view taken along the waveguide axis WG1. FIG. 15D is a sectional view taken along line XVd-XVd in FIG. 15C. FIG. 15C is a sectional view taken along line XVc-XVc in FIG. 15D. As shown in FIGS. 15C and 15D, after the protective film 90 is formed, an emitter electrode 94a and a collector electrode 94b (metal electrodes) are formed. For example, the emitter electrode 94a and the collector electrode 94b are formed by forming a lift-off mask and then forming over the lift-off mask a metal film for forming the emitter electrode 94a and the collector electrode 94b. By using a lift-off process, the lift-off mask is removed to form the emitter electrode 94a and the collector electrode 94b. If necessary, a back metal film 94c may be formed on the back surface of the InP substrate 61 after polishing. The thus-fabricated substrate product is cleaved to form a laser bar.

Although preferred embodiments have been described in order to illustrate the principles of the present invention, those skilled in the art will appreciate that various changes in configuration and details may be made without departing from such principles. The present invention is not limited to any particular configuration disclosed in the foregoing embodiments. Thus, all modifications and changes that come within the scope and spirit of the claims are to be claimed.

What is claimed is:

1. A semiconductor laser comprising:
a substrate having a principal surface;
an active region having a top surface and a side surface, the active region including a plurality of quantum well structures arranged in a direction of a first axis intersecting the principal surface of the substrate;
a semiconductor mesa having first and second portions arranged in a direction of a waveguide axis above the principal surface of the substrate, the semiconductor mesa including the active region;
a first semiconductor region of a first conductivity type on the top and side surfaces of the active region in the first portion of the semiconductor mesa; and
a collector region on the side surface of the active region in the second portion of the semiconductor mesa.

2. The semiconductor laser according to claim 1, wherein each of the quantum well structures includes a first well layer, a second well layer, a first barrier layer, and a second barrier layer,
the first barrier layer separates the first well layer from the second well layer, and
the first well layer separates the first barrier layer from the second barrier layer.

3. The semiconductor laser according to claim 2, wherein the active region includes a plurality of unit cells arranged in the direction of the first axis,
each of the unit cells includes the first well layer, the second well layer, the first barrier layer, and the second barrier layer, and
the first barrier layer has a thickness smaller than that of the second barrier layer.

4. The semiconductor laser according to claim 1, wherein each of the quantum well structures includes a barrier layer extending in a plane intersecting the direction of the first axis,
the barrier layer is partially or completely doped with a dopant of the first conductivity type.

5. The semiconductor laser according to claim 1, wherein the collector region includes a metal electrode extending in the direction of the first axis on the side surface of the active region.

6. The semiconductor laser according to claim 1, wherein the collector region includes a second semiconductor region of the first conductivity type on the side surface of the active region.

7. The semiconductor laser according to claim 6, wherein the semiconductor laser includes a plurality of basic structures, each of which includes the first semiconductor region, the first portion of the semiconductor mesa, the second semiconductor region, and the second portion of the semiconductor mesa,
the basic structures are periodically arranged in the direction of the waveguide axis, and
the first semiconductor regions and the second semiconductor regions are alternately arranged in the direction of the waveguide axis.

8. The semiconductor laser according to claim 1, further comprising a first electrode and a second electrode,
wherein the first electrode is electrically connected to the first semiconductor region of the first conductivity type, and
the second electrode is electrically connected to the collector region.
